(19) United States
(12) Patent Application Publication
(10) Pub. No.: US 2011/0212013 A1
(43) Pub. Date: Sep. 1, 2011

(54) ADDITION OF HYDROGEN AND/OR NITROGEN CONTAINING COMPOUNDS TO THE NITROGEN-CONTAINING SOLVENT USED DURING THE AMMONOTHERMAL GROWTH OF GROUP-III NITRIDE CRYSTALS

(75) Inventors: Siddha Pimputkar, Goleta, CA (US); Derrick S. Kamber, Goleta, CA (US); James S. Speck, Goleta, CA (US); Shuji Nakamura, Santa Barbara, CA (US)

(73) Assignee: THE REGENTS OF THE UNIVERSITY OF CALIFORNIA, Oakland, CA (US)

(21) Appl. No.: 13/128,098

(22) PCT Filed: Nov. 4, 2009
(86) PCT No.: PCT/US09/63287

§ 371 Date: May 6, 2011

(30) Foreign Application Priority Data
Nov. 7, 2008 (US) 61112558

(51) Int. Cl. C01B 21/06; C01B 21/072; C30B 19/08

(52) U.S. Cl. 423/412; 423/406; 423/409; 117/56; 117/65

(57) ABSTRACT

A method for adding hydrogen-containing and/or nitrogen-containing compounds to a nitrogen-containing solvent used during ammonothermal growth of group-Ill nitride crystals to offset decomposition products formed from the nitrogen-containing solvent, in order to shift the balance between the reactants, i.e. the nitrogen-containing solvent and the decomposition products, towards the reactant side.

### CROSS REFERENCE TO RELATED APPLICATIONS

This application claims the benefit under 35 U.S.C. Section 119(e) of co-pending and commonly-assigned application:

U.S. Provisional Application Ser. No. 61/112,558, filed on Nov. 7, 2008, by Siddha Pimputkar, Derrick S. Kamber, James S. Speck and Shuji Nakamura, entitled “ADDITION OF HYDROGEN AND/OR NITROGEN CONTAINING COMPOUNDS TO THE NITROGEN-CONTAINING SOLVENT USED DURING THE AMMONOTHERMAL GROWTH OF GROUP-III NITRIDE CRYSTALS TO OFFSET THE DECOMPOSITION OF THE NITROGEN-CONTAINING SOLVENT AND/OR MASS LOSS DUE TO DIFFUSION OF HYDROGEN OUT OF THE CLOSED VESSEL,” attorney's docket number 30794.298-US-P1 (2009-286-1);

which application is incorporated by reference herein.

This application is related to the following co-pending and commonly-assigned U.S. patent applications:

U.S. Utility patent application Ser. No. 11/921,396, filed on Nov. 30, 2007, by Kenji Fujito, Tadao Hashimoto and Shuji Nakamura, entitled “METHOD FOR GROWING GROUP-III NITRIDE CRYSTALS IN SUPERCRITICAL AMMONIA USING AN AUTOCLAVE,” attorneys docket number 30794.129-US-WO (2005-339-2), which application claims the benefit under 35 U.S.C. Section 365(c) of PCT Utility Patent Application Serial No. US2005/024239, filed on Jul. 8, 2005, by Kenji Fujito, Tadao Hashimoto and Shuji Nakamura, entitled “METHOD FOR GROWING GROUP-III NITRIDE CRYSTALS IN SUPERCRITICAL AMMONIA USING AN AUTOCLAVE,” attorneys' docket number 30794.129-WO-01 (2005-339-1);

U.S. Utility patent application Ser. No. 11/784,339, filed on Apr. 6, 2007, by Tadao Hashimoto, Makoto Saito, and Shuji Nakamura, entitled “METHOD FOR GROWING LARGE SURFACE AREA GALLIUM NITRIDE CRYSTALS IN SUPERCRITICAL AMMONIA AND LARGE SURFACE AREA GALLIUM NITRIDE CRYSTALS,” attorneys docket number 30794.179-US-U1 (2006-204), which application claims the benefit under 35 U.S.C. Section 119(e) of U.S. Provisional Patent Application Ser. No. 60/790,310, filed on Apr. 7, 2006, by Tadao Hashimoto, Makoto Saito, and Shuji Nakamura, entitled “A METHOD FOR GROWING LARGE SURFACE AREA GALLIUM NITRIDE CRYSTALS IN SUPERCRITICAL AMMONIA AND LARGE SURFACE AREA GALLIUM NITRIDE CRYSTALS,” attorneys docket number 30794.179-US-P1 (2006-204);

U.S. Utility patent application Ser. No. 11/765,629, filed on Jun. 20, 2007, by Tadao Hashimoto, Hitoshi Sato and Shuji Nakamura, entitled “OPTO-ELECTRONIC AND ELECTRONIC DEVICES USING N-FACE OR M-PLANE GaN SUBSTRATE PREPARED WITH AMMONOTHERMAL GROWTH,” attorneys' docket number 30794.184-US-U1 (2006-666), which application claims the benefit under 35 U.S.C. Section 119(e) of U.S. Provisional Application Ser. No. 60/815,507, filed on Jun. 21, 2006, by Tadao Hashimoto, Hitoshi Sato, and Shuji Nakamura, entitled “OPTO-ELECTRONIC AND ELECTRONIC DEVICES USING N-FACE GaN SUBSTRATE PREPARED WITH AMMONOTHERMAL GROWTH,” attorneys' docket number 30794.184-US-P1 (2006-666);

U.S. Utility patent Ser. No. 12/234,244, filed on Sep. 19, 2008, by Tadao Hashimoto and Shuji Nakamura, entitled “GALLIUM NITRIDE BULK CRYSTALS AND THEIR GROWTH METHOD,” attorneys' docket number 30794.244-US-U1 (2007-809), which application claims the benefit under 35 U.S.C. Section 119(e) of U.S. Provisional Patent Application Ser. No. 60/973,662, filed on Sep. 19, 2007, by Tadao Hashimoto and Shuji Nakamura, entitled “GALLIUM NITRIDE BULK CRYSTALS AND THEIR GROWTH METHOD,” attorneys' docket number 30794.244-US-P1 (2007-809-1);

U.S. Utility patent application Ser. No. 11/977,661, filed on Oct. 25, 2007, by Tadao Hashimoto, entitled “METHOD FOR GROWING GROUP-III NITRIDE CRYSTALS IN A MIXTURE OF SUPERCRITICAL AMMONIA AND NITROGEN, AND GROUP-III NITRIDE CRYSTALS GROWN THEREBY,” attorneys' docket number 30794.253-US-U1 (2007-774-2), which application claims the benefit under 35 U.S.C. Section 119(e) of U.S. Provisional Application Ser. No. 60/854,567, filed on Oct. 25, 2006, by Tadao Hashimoto, entitled “METHOD FOR GROWING GROUP-III NITRIDE CRYSTALS IN MIXTURE OF SUPERCRITICAL AMMONIA AND NITROGEN AND GROUP-III NITRIDE CRYSTALS,” attorneys' docket number 30794.253-US-P1 (2007-774);

U.S. Utility patent application Ser. No. ______, filed on same date herewith, by Siddha Pimputkar, Derrick S. Kamber, Makoto Saito, Steven P. DenBaars, James S. Speck and Shuji Nakamura, entitled “GROUP-III NITRIDE MONOCRYSTAL WITH IMPROVED CRYSTAL QUALITY GROWN ON AN ETCHED-BACK SEED CRYSTAL AND METHOD OF PRODUCING THE SAME,” attorneys' docket number 30794.288-US-U1 (2009-154-2), which application claims the benefit under 35 U.S.C. Section 119(e) of U.S. Provisional Application Ser. No. 61/111,644, filed on Nov. 5, 2008, by Siddha Pimputkar, Derrick S. Kamber, Makoto Saito, Steven P. DenBaars, James S. Speck and Shuji Nakamura, entitled “GROUP-III NITRIDE MONOCRYSTAL WITH IMPROVED CRYSTAL QUALITY GROWN ON AN ETCHED-BACK SEED CRYSTAL AND METHOD OF PRODUCING THE SAME,” attorney's docket number 30794.288-US-P1 (2009-154-1);

P.C.T. International Patent Application Serial No. PCT/US09/______, filed on same date herewith, by Derrick S. Kamber, Siddha Pimputkar, Makoto Saito, Steven P. DenBaars, James S. Speck and Shuji Nakamura, entitled “GROUP-III NITRIDE MONOCRYSTAL WITH IMPROVED PURITY AND METHOD OF PRODUCING THE SAME,” attorneys' docket number 30794.295-WO-U1 (2009-282-2), which application claims the benefit under 35 U.S.C. Section 119(e) of U.S. Provisional Application Ser. No. 61/112,555, filed on Nov. 7, 2008, by Derrick S. Kamber, Siddha Pimputkar, Makoto Saito, Steven P. DenBaars, James S. Speck and Shuji Nakamura, entitled “GROUP-III NITRIDE MONOCRYSTAL WITH IMPROVED PURITY AND METHOD OF PRODUCING THE SAME,” attorney's docket number 30794.295-US-P1 (2009-282-1);

P.C.T. International Patent Application Serial No. PCT/US09/______, filed on same date herewith, by Siddha Pimputkar, Derrick S. Kamber, James S. Speck and Shuji Nakamura, entitled “REACTOR DESIGNS FOR USE IN AMMONOTHERMAL GROWTH OF GROUP-III NITRIDE CRYSTALS,” attorneys' docket number 30794.296-WO-U1 (2009-283/285-2), which application claims the benefit under 35 U.S.C. Section 119(e) of U.S. Provisional Application Ser. No. 61/112,560, filed on Nov. 7, 2008, by Siddha Pimputkar, Derrick S. Kamber, James S. Speck and Shuji Nakamura, entitled “REACTOR DESIGNS FOR USE IN AMMONOTHERMAL GROWTH OF GROUP-III NITRIDE CRYSTALS,” attorney's docket number 30794.296-US-P1 (2009-283/285-1);

P.C.T. International Patent Application Serial No. PCT/US09/______, filed on same date herewith, by Siddha Pimputkar, Derrick S. Kamber, James S. Speck and Shuji Nakamura, entitled “NOVEL VESSEL DESIGNS AND RELATIVE PLACEMENTS OF THE SOURCE MATERIAL AND SEED CRYSTALS WITH RESPECT TO THE VESSEL FOR THE AMMONOTHERMAL GROWTH OF GROUP-III NITRIDE CRYSTALS,” attorneys' docket number 30794.297-WO-U1 (2009-284-2), which application claims the benefit under 35 U.S.C. Section 119(e) of U.S. Provisional Application Ser. No. 61/112,552, filed on Nov. 7, 2008, by Siddha Pimputkar, Derrick S. Kamber, James S. Speck and Shuji Nakamura, entitled “NOVEL VESSEL DESIGNS AND RELATIVE PLACEMENTS OF THE SOURCE MATERIAL AND SEED CRYSTALS WITH RESPECT TO THE VESSEL FOR THE AMMONOTHERMAL GROWTH OF GROUP-III NITRIDE CRYSTALS,” attorney's docket number 30794.297-US-P1 (2009-284-1);

P.C.T. International Patent Application Serial No. PCT/US09/______, filed on same date herewith, by Siddha Pimputkar, Derrick S. Kamber, James S. Speck and Shuji Nakamura, entitled “CONTROLLING RELATIVE GROWTH RATES OF DIFERENT EXPOSED CRYSTALLOGRAPHIC FACETS OF A GROUP-III NITRIDE CRYSTAL DURING THE AMMONOTHERMAL GROWTH OF A GROUP-III NITRIDE CRYSTAL,” attorneys' docket number 30794.299-WO-U1 (2009-287-2), which application claims the benefit under 35 U.S.C. Section 119(e) of U.S. Provisional Application Ser. No. 61/112,545, filed on Nov. 7, 2008, by Siddha Pimputkar, Derrick S. Kamber, James S. Speck and Shuji Nakamura, entitled “CONTROLLING RELATIVE GROWTH RATES OF DIFERENT EXPOSED CRYSTALLOGRAPHIC FACETS OF A GROUP-III NITRIDE CRYSTAL DURING THE AMMONOTHERMAL GROWTH OF A GROUP-III NITRIDE CRYSTAL,” attorney's docket number 30794.299-US-P1 (2009-287-1), and

P.C.T. International Patent Application Serial No. PCT/US09/______, filed on same date herewith, by Siddha Pimputkar, Derrick S. Kamber, James S. Speck and Shuji Nakamura, entitled “USING BORON-CONTAINING COMPOUNDS, GASSES AND FLUIDS DURING AMMONOTHERMAL GROWTH OF GROUP-III NITRIDE CRYSTALS,” attorneys' docket number 30794.300-WO-U1 (2009-288-2), which application claims the benefit under 35 U.S.C. Section 119(e) of U.S. Provisional Application Ser. No. 61/112,550, filed on Nov. 7, 2008, by Siddha Pimputkar, Derrick S. Kamber, James S. Speck and Shuji Nakamura, entitled “USING BORON-CONTAINING COMPOUNDS, GASSES AND FLUIDS DURING AMMONOTHERMAL GROWTH OF GROUP-III NITRIDE CRYSTALS,” attorney's docket number 30794.300-US-P1 (2009-288-1);

all of which applications are incorporated by reference herein.

### BACKGROUND OF THE INVENTION

1. Field of the Invention

This invention relates to ammonothermal growth of group-III nitrides.

2. Description of the Related Art

Ammonothermal growth of group-III nitrides, for example, GaN, involves placing, within a reactor vessel, group-III-containing source materials, group-III nitride seed crystals, and a nitrogen-containing solvent, such as ammonia, sealing the vessel and heating the vessel to conditions such that the vessel is at elevated temperatures (between 23° C. and 1000° C.) and high pressures (between 1 atm and, for example, 30,000 atm). Under these temperatures and pressures, the nitrogen-containing solvent may become a supercritical fluid which normally exhibits enhanced solubility of the group-III-containing materials into solution. The solubility of the group-III-containing materials into the nitrogen-containing solvent is dependent on the temperature, pressure and density of the solvent, among other things. By creating two different zones within the vessel, it is possible to establish a solubility gradient where, in one zone, the solubility will be higher than in a second zone. The group-III-containing source materials are then preferentially placed in the higher solubility zone and the seed crystals in the lower solubility zone. By establishing fluid motion of the solvent with the dissolved source materials between these two zones, for example, by making use of natural convection, it is possible to transport the group-III-containing source materials from the higher solubility zone to the lower solubility zone where the group-III-containing source materials are deposited onto the seed crystals.

However, much of the ammonia (NH₃) used in the ammonothermal growth will eventually decompose into nitrogen (N₂) and hydrogen (H₂) products. The H₂, which is a very light molecule, has the tendency to diffuse out of the walls of the vessel, leading to mass loss within the closed vessel. Moreover, the decomposition reduces the effective amount of nitrogen-containing solvent available for ammonothermal growth of the group-III nitride.

Thus, there is a need in the art for techniques that add N₂ and/or H₂ products to the nitrogen-containing solvent during the ammonothermal growth to offset this decomposition that occurs. The present invention satisfies this need.

### SUMMARY OF THE INVENTION

To overcome the limitations in the prior art described above, and to overcome other limitations that will become apparent upon reading and understanding the present invention, the present invention discloses a method of fabricating a group-III nitride crystal in a closed vessel, comprising adding a hydrogen-containing and/or nitrogen-containing compound to a nitrogen-containing solvent used during ammonothermal growth of the group-III nitride crystal on one or more seed crystals, to offset the decomposition of the nitrogen-containing solvent and mass loss due to diffusion of hydrogen out of the closed vessel.

As a result, the method of the present invention increases the yield of a group-III nitride crystal that is grown in a given time period.

For example, the present invention discloses a method for ammonothermally growing group-III nitride crystal(s) in a reactor vessel, comprising using a nitrogen-containing solvent to dissolve and transport group-III-containing source material(s) to group-III seed crystal(s), wherein one or more decomposition products form during one or more decomposition reactions of the nitrogen-containing solvent; growing the group-III nitride crystal(s) on the seed crystal(s) using the dissolved source materials; and adding one or more hydrogen-containing and/or nitrogen-containing compounds to the vessel, during or before the growing step, wherein the hydrogen-containing and/or nitrogen-containing compounds effect equilibrium of the decomposition reactions of the solvent.

The balance between the nitrogen-containing solvent and the decomposition products may be shifted according to Le Chatelier's principle to increase molar amounts of non-decomposed nitrogen-containing solvent and reduce decomposition of the nitrogen-containing solvent.

The hydrogen-containing and/or nitrogen-containing compounds may comprise different materials, for example, H₂, or one or more additional amounts of the decomposition products (e.g., H₂, or N₂ and H₂). The nitrogen-containing compound may comprise N₂. If the nitrogen-containing solvent is ammonia, NH₃, the additional amounts of the decomposition products may comprise at least 0.01 moles of H₂, or at least 0.01 moles of H₂ and at least 0.01 moles of N₂, for example.

The additional amounts of the decomposition products typically comprise exogenous matter that is exogenous to the decomposition reactions.

In another example, the additional amounts of the decomposition products are at least equivalent, within a factor of 100, to a molar number of the decomposition products that comprise the hydrogen-containing (e.g., H₂ or a hydrogen moiety or amount) and/or nitrogen-containing (N₂ or a nitrogen moiety or amount) compounds, wherein the molar number of the decomposition products that comprise H₂ or a hydrogen moiety, is determined by obtaining a molar number of the nitrogen-containing solvent as a function of equilibrium constant K, and fugacity ratio Kᵥ of the decomposition reactions, at a temperature and pressure of the nitrogen-containing solvent used during the growing; and obtaining the molar number of the decomposition products comprising hydrogen as a function of the molar number of the nitrogen-containing solvent.

The additional amounts of decomposition products may be such that the nitrogen-containing solvent, comprising NH₃, has a molar ratio of more than what would be present in equilibrium during growth without the addition of one or more additional decomposition products to the vessel.

The method may further comprise forming, in a first zone of the vessel, a solution of the source materials in the nitrogen-containing solvent; and transporting the solution from the first zone to the seed crystal in a second zone of the vessel by establishing motion of the nitrogen-containing solvent between the first zone and the second zone, so that the group-III nitride crystal is grown on the seed crystals in the second zone.

The method may further comprise (1) placing, within the vessel, the source materials in a first zone of the vessel, and the seed crystals in a second zone of the vessel, wherein the solvent is in the first zone and the second zone; (2) sealing the vessel; (3) heating the vessel to elevated temperatures and high pressures so that the solvent becomes a supercritical fluid and exhibits enhanced solubility of the source materials into the solvent, wherein the solubility of the source materials into the solvent is dependent on the solvent's temperature, pressure and density; (4) establishing a solubility gradient between the first zone and the second zone, such that a solubility of the source materials in the solvent in the first zone is higher than a solubility of the source materials in the solvent in the second zone; (5) establishing motion of the solvent between the first zone and the second zone to transport the source materials in the solvent from the first zone to the second zone, to grow the group-III nitride crystal on the seed crystals; and (6) adding the hydrogen-containing and/or nitrogen-containing compound to the solvent in the vessel after step (2) or at any time during the process or method.

The present invention further discloses a GaN crystal grown using the method of the present invention.

### BRIEF DESCRIPTION OF THE DRAWINGS

Referring now to the drawings in which like reference numbers represent corresponding parts throughout:

FIG. 1 is extrapolated data of fugacity constant for NH₃ at various temperatures and pressures (where the numbers in the box legend are the temperature in Kelvin (K));

FIG. 2 is theoretically calculated equilibrium NH₃ molar ratio at various temperatures, in degrees Celsius, and pressures (atm).

FIG. 3 is a schematic of a high-pressure vessel according to an embodiment of the present invention.

FIG. 4 is a flow chart that describes one example of ammonothermal growth according to the present invention.

FIG. 5 is a flow chart that describes a method of determining an amount of decomposition product to add to the vessel.

FIG. 6 is a flow chart that describes another example of ammonothermal growth according to the present invention.

### DETAILED DESCRIPTION OF THE INVENTION

In the following description of the preferred embodiment, reference is made to a specific embodiment in which the invention may be practiced. It is to be understood that other embodiments may be utilized and structural changes may be made without departing from the scope of the present invention.

Technical Description

Theoretical Calculations

The following theoretical calculations are presented solely for the purpose of demonstrating the concept of one embodiment of the current invention. No attempt whatsoever was made to ensure that the model presented is the most accurate and suitable for the particular regime present during the growth process, yet the qualitative information provided by this model is sufficient to portray the concept. One reason for not being able to provide a qualitative accurate model is due to insufficient experimental data and theoretical models for the extreme conditions which are experienced during growth.

The model below is based on the ideal gas or ideal gas-like conditions and as such will only provide values within realm of this assumption. The behavior of the supercritical fluid during growth may be slightly or significantly different than the physics predicted with this simplified model.

It is well known that NH₃ (gas, g) ultimately dissociates into N₂ (gas, g) and H₂ (gas, g) in the following overarching reaction.

$${NH}_{3} ( g ) \begin{matrix}\to \\ ←\end{matrix} \frac{3}{2} {H}_{2} ( g ) + \frac{1}{2} {N}_{2} ( g ) \qquad ( 1 )$$

H₂ and N₂ are the decomposition products of the reaction. Since the ammonothermal growth of group-III nitride crystals is carried out at high pressure and high temperature NH₃, it is important to estimate the degree of NH₃ dissociation in this process. The relationship among the equilibrium constant, K, fugacity ratio, Kᵥ, total system pressure P_{T}, equilibrium molar number of NH₃, n_{NH3}, equilibrium molar number of N₂, n_{N2}, and equilibrium molar number of H₂, n_{H2}, is given in this particular model assuming ideal gas conditions as follows [1]:

$$\frac{{n}_{NH 3}}{{n}_{N 2}^{1 / 2} \cdot {n}_{H 2}^{3 / 2}} \cdot {K}_{v} \cdot {[ \frac{{P}_{T}}{{n}_{NH 3} + {n}_{N 2} + {n}_{H 2}} ]}^{1 - ( \frac{1}{2} + \frac{3}{2} )} = K \qquad ( 2 )$$

Setting the equilibrium molar number of NH₃ to x and starting with non-equilibrium conditions n_{NH3}=0, n_{N2}=½ moles, and n_{H2}=3/2 moles, the amount of ammonia in equilibrium will be given by the following relationships:

n_{NH3}=x

n_{N2}=½−½·x

n_{H2}=3/2-3/2·x (3)

Where under these assumptions and initial conditions the mole fraction of ammonia can be determined using the following formula:

mole fraction NH₃=x/(2−x) (3.1)

Using these relationships, one can obtain the relationship among K, P_{T}, Kᵥ and x which is a quadratic equation in x:

$$( \frac{{P}_{T} K}{{K}_{v}} + 0.77 ) {x}^{2} - ( \frac{2 {P}_{T} K}{{K}_{v}} + 1.54 ) x + \frac{{P}_{T} K}{{K}_{v}} = 0 \qquad ( 4 )$$

Equilibrium constants K at various temperatures are available in the literature [2]: they are 0.0079, 0.0050, 0.0032, 0.0020, 0.0013, 0.00079, and 0.00063 at 700K, 750K, 800K, 850K, 900K, 950K, and 1000K, respectively. Although Kᵥ values at high temperature and high pressure are not readily available, reasonable extrapolation is possible from existing data [3].

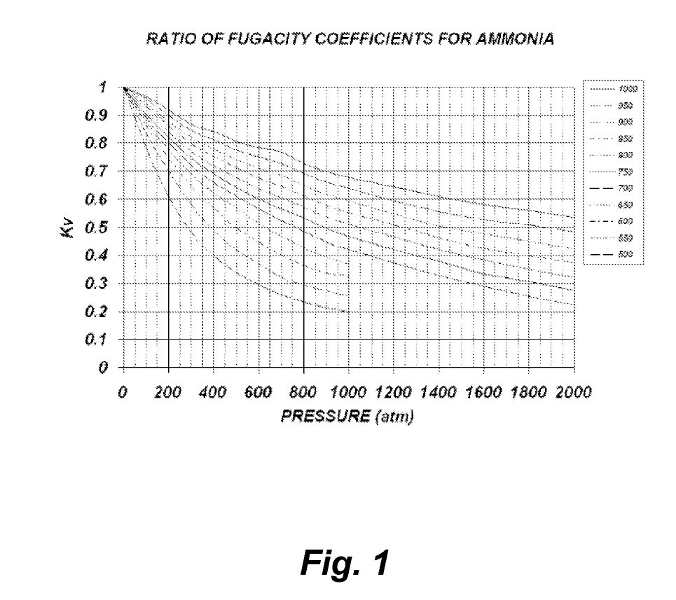

FIG. 1 is a graph that shows the extrapolated Kᵥ values at various temperatures and pressures. Using these data, the equilibrium NH₃ molar ratio at various temperatures and pressures was calculated as shown in the graph of FIG. 1.

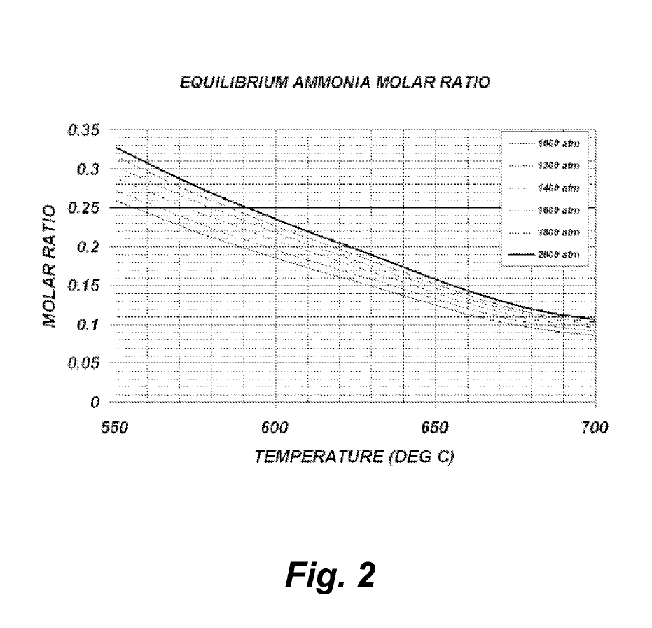

In FIG. 2, the majority of charged NH₃ is dissociated into N₂ and H₂ at the typical temperature and pressure conditions for ammonothermal growth of group-III nitride crystals. Based on this model, less than 35% of the original amount of NH₃ acts as the crystal growth medium. Although it appears from the reaction formula in this particular model, which may not accurately reproduce the conditions present during growth in the supercritical regime of the nitrogen-containing supercritical fluid, that increasing the pressure by charging more NH₃ will help in preventing NH₃ dissociation, even doubling the pressure (i.e. 1000 atm to 2000 atm) results in a minor increase of the NH₃ molar ratio above 500° C. Since group-III nitride crystals have high melting points, crystal growth needs a relatively high temperature as compared to other semiconductor materials and oxide crystals. For example, GaN with a commercially usable quality may be grown at temperatures higher than 500° C. Therefore, in order to grow high-quality group-III nitride crystals with a commercially practical growth rate, it is important to prevent NH₃ dissociation at temperatures above 500° C.

Adding extra decomposition products (N₂ and/or H₂) in the vessel will effectively reduce the amount of NH₃ dissociation. When, for example, one considers the case of P_{T}=300 atm, T=700 K, K=0.0091, Kᵥ=0.72, the equilibrium mole percentage of gases present in the equilibrium solution are: n_{NH3}=41.6 mol %, n_{N2}=14.6 mol %, n_{H2}=43.8 mol %, wherein mol % is mole percentage.

The equilibrium mole fractions of NH₃, N₂, H₂ can be altered through the addition of, for example, H₂ or N₂. Based on Le Chatelier's principle, which states qualitatively that a system will counteract the imposed change on a system, the balance of the products and reactants of equation (1) will shift towards the reactant side (since additional products were added) resulting in an increase in ammonia.

The actual equilibrium amounts of NH₃, N₂, H₂ present in the vessel with any given initial amounts of NH₃, N₂, H₂ can be determined using the following method: starting with the previous assumption of an ideal gas or ideal gas-like system, equation (2) will always hold. If one starts with a stoichiometric solution, meaning the ratio of the sum of all nitrogen atoms and the sum off all hydrogen atoms will be exactly 1:3, or in other words, there is exactly enough hydrogen atoms and nitrogen atoms present in the vessel to create a solution containing only ammonia without any residual hydrogen or nitrogen remaining, then equation (4) may be used to determine the equilibrium mole number of ammonia.

If, on the other hand, the present invention adds additional decomposition products to the vessel, the solution is no longer stoichiometric, meaning if the present invention were to make as much ammonia as possible with the given nitrogen and hydrogen atoms, there would be some remaining nitrogen or hydrogen which cannot be bonded to form ammonia, since there is insufficient hydrogen or nitrogen, respectively, present; under these conditions, the present invention refers to equation (2) to determine the final equilibrium amount of ammonia, hydrogen, and nitrogen. This can be done using the following algorithm: first, determine the relevant K, Kᵥ, at the given P_{T} and T. Plug these numbers into equation (2). Plug in the molar numbers of n_{NH3}, n_{H2}, and n_{N2} as given initially (i.e. not necessarily equilibrium conditions). Calculate the left hand side and the right hand side of equation (2) and if they are not equal within the acceptable margin of error (for example 0.1%), then the values of n_{NH3}, n_{H2}, n_{N2} need to be adjusted according to the following equation, wherein Δx symbolizes the increase in amount of ammonia in the system and has the units of mole (if one wishes to decrease the amount of ammonia, one simply inserts a negative numeric value for Δx):

n_{NH3}(new)=n_{NH3}(old)+Δx

n_{N2}(new)=n_{N2}(old)−½*Δx

n_{H2}(new)=n_{H2}(old)−3/2*Δx (5)

These new values for n_{NH3}, n_{H2}, n_{N2} are then plugged into equation (2), along with any relevant changes to K, Kᵥ, due to any relevant change to P_{T} given the change in absolute number of moles of gas present in the vessel (±Δx) and the new value for the left hand side is determined. Again, if accuracy is not deemed sufficient, another modification to the values can be made according to the set of equations (5). This process is repeated until the left hand side and right hand side of the equation (2) are equal to one another within an acceptable margin of error. The found values for n_{NH3}, n_{H2}, n_{N2} are then the equilibrium values for the vessel given the initial conditions.

In one embodiment, for example, the initial numbers as needed to be plugged into equation (2) might be the initial conditions set forth by the user, e.g., the reactor is filled with 1 mole of NH₃ and 1 mole of N₂, in which case the starting point for the calculation would be n_{NH3}=1, n_{N2}=1, and n_{H2}=0. By iterating through Ax the present invention eventually obtains the equilibrium amounts. Therefore, the system may originally not in equilibrium, or present in stoichiometric amounts as given by equation 1. Generally speaking, the condition of being stoichiometric or not may be selected by the user, and the condition of equilibrium may be set by thermodynamics. Therefore, it is possible for a system to be in equilibrium, but the molar numbers present are not stoichiometric with respect to equation (1).

The present invention is not limited to the use of NH₃ as the nitrogen-containing solvent. Other nitrogen-containing solvents may also be used, e.g., but not limited to, hydrazine (N₂H₄), triazane (N₃H₅), tetrazane (N₄H₆), triazene (N₃H₃), diimine (N₂H₂), N₂ and nitrene (NH). For the particular nitrogen-containing solvent selected, dissociation reactions such as equation (1), equilibrium constants K, fugacity ratios K_{V}, molar ratios for the nitrogen-containing solvents and their decomposition products, as a function of pressure of temperature, may be obtained through experiments. Then, as described above, using equations analogous to equations (1)-(5) above, the desired amount of additional decomposition product may be determined and added. Using equations (1)-(5), the amount of decomposition can be estimated along with the effect of adding any desired amount of additional decomposition products to the vessel. The actual amount of additional decomposition products added to the vessel can only be determined based on the desired result from the given growth run and may not be the same for all experiments. Note that it is never possible to eliminate all possible decomposition products through the addition of any number of decomposition products as K is finite.

Apparatus Description

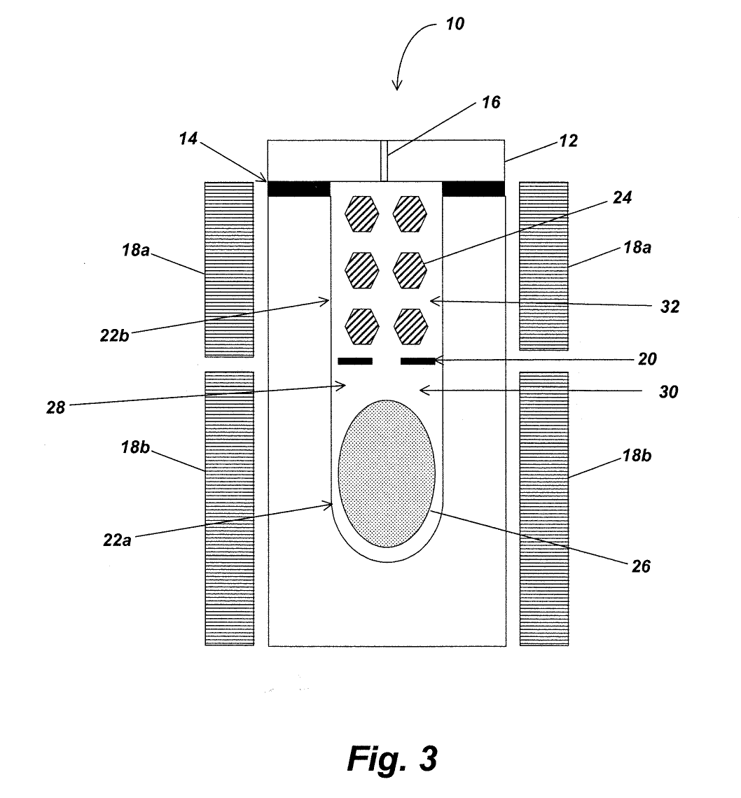

FIG. 3 is a schematic of an ammonothermal growth system comprising a high-pressure reaction vessel 10 according to one embodiment of the present invention. The vessel may include a lid 12, gasket 14, inlet and outlet port 16, and external heaters/coolers 18a and 18b. A baffle plate 20 divides the interior of the vessel 10 into two zones 22a and 22b, wherein the zones 22a and 22b are separately heated and/or cooled by the external heaters/coolers 18b and 18a, respectively. An upper zone 22b may contain one or more group-III nitride seed crystals 24 and a lower zone 22a may contain one or more group-III-containing source materials 26, although these positions may be reversed in other embodiments. Both the group-III nitride seed crystals 24 and group-III-containing source materials 26 may be contained within baskets or other containment devices, which are typically comprised of an Ni—Cr alloy. The vessel 10 and lid 12, as well as other components, may also be made of a Ni—Cr based alloy. Finally, the interior of the vessel 10 is filled with a solvent 28 to accomplish the ammonothermal growth.

According to the present invention, the solvent 28 is a nitrogen-containing solvent 28 and thus contains a molar amount of a nitrogen-containing compound (e.g., NH₃), in the first or lower zone 22a and second or upper zone 22b, that is greater than 0.01 moles, as well as decomposition products 30. The solvent 28 and vessel 10 may also contain one or more hydrogen-containing 32 and/or nitrogen-containing compounds, such as additional amounts of the decomposition products 30. The solvent 28 and vessel 10 may contain an amount of H₂, e.g., in the first zone 22a and second zone 22b, of at least 0.01 moles. Thus, the solvent 28 may comprise just one or more nitrogen-containing compounds, or may comprise both one or more nitrogen-containing compounds and additional hydrogen-containing and/or nitrogen-containing compounds 32. The nitrogen-containing solvent 28 may comprise a nitrogen moiety or amount, such as in NH₃, the hydrogen-containing compound 32 may comprise a hydrogen moiety or amount, such as H₂, and the nitrogen-containing compound may comprise a nitrogen moiety or amount, such as N₂. Thus, the one or more hydrogen-containing compounds 32 may be one or more hydrogen-containing and nitrogen-containing compounds, comprising both nitrogen and hydrogen amounts, or there may be separate compounds 32, with one or more compounds comprising hydrogen amount(s) and one or more compounds comprising nitrogen amount(s).

Process Description

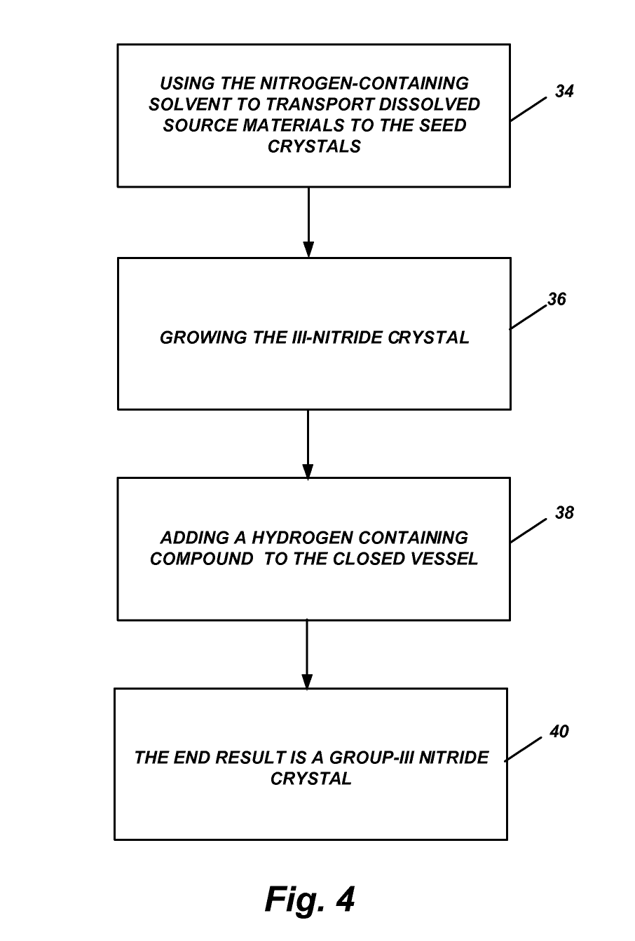

FIG. 4 is a flow chart illustrating a method for ammonothermally growing one or more group-III nitride crystals in a reactor vessel, such as the vessel 10 in FIG. 3, for example. The method comprises the following steps.

Block 34 represents using the solvent 28 to dissolve and transport one or more dissolved source materials 26 to the one or more seed crystals 24, wherein one or more decomposition products 30 form during one or more decomposition reactions (e.g., equation (1)) of the solvent 28. The solvent 28 is typically a nitrogen-containing solvent 28 and the step further comprises forming, in a first zone 22a of the vessel 10, a solution of the source materials 26 in the solvent 28 in the first zone 22a; transporting the solvent 28 and solution to the seed crystals 24 in a second zone 22b by establishing motion of the solvent 28 between the first zone 22a and the second zone 22b; and causing the source materials in the solvent 28 to come out of solution and deposit on the seed crystals 24.

Block 36 represents growing the group-III nitride crystal on the seed crystals 24 using the dissolved source materials 26 transported by the solvent 28.

Block 38 represents adding one or more hydrogen-containing 32 and/or nitrogen-containing compounds 32, or one or more compounds 32 containing both hydrogen and nitrogen, or hydrogen and nitrogen separately, to the solvent 28 in the vessel 10, during or before the growing step, wherein the hydrogen-containing 32 and/or nitrogen-containing compound 32 affects equilibrium of the decomposition reactions (e.g., equation (1)), to shift a balance between the nitrogen-containing solvent 28 and the decomposition products 30 according to Le Chatelier's principle, for example. The hydrogen-containing compound 32 may comprise H₂. The nitrogen-containing compound 32 may comprise N₂. The hydrogen-containing compound 32 may comprise one or more additional amounts of the decomposition products 30. The additional amounts of decomposition products are typically exogenous matter that is exogenous to the decomposition reactions (such as equation (1)). For example, the additional amounts of the decomposition products 30 is additional matter that is the same/similar material as the decomposition product(s) 30 but obtained from a source external to the decomposition reactions.

At least one of the decomposition products 30 and at least some of the additional amounts of the decomposition products 30 may comprise H₂, or H₂ and N₂ (e.g., when the nitrogen-containing solvent 28 is NH₃), or other hydrogen amounts. If the nitrogen-containing solvent 28 is NH₃, the additional amounts of the decomposition products 30 may comprise at least 0.01 moles of H₂, at least 0.01 moles of H₂ and at least 0.01 moles of N₂, or additional amounts of the decomposition products 30 such that the molar ratio or amount of the NH₃ is greater than what it would have been inside the vessel 10 if no additional decomposition products 30 were added.

The balance between the nitrogen-containing solvent 28 and the decomposition products 30 may be shifted according to Le Chatelier's principle to increase molar amounts of non-decomposed nitrogen-containing solvent 28 and reduce decomposition of the nitrogen-containing solvent 28.

Thus, in a method of fabricating a group-III nitride crystal in a closed vessel 10, the adding of a hydrogen-containing and/or nitrogen-containing compound 32 to the nitrogen-containing solvent 28 used with source materials during ammonothermal growth of the group-III nitride crystal on a seed crystal may offset the decomposition of the nitrogen-containing solvent 28 and/or mass loss due to diffusion of H₂ out of the closed vessel 10.

Block 40 represents the end result of the method, a group-III nitride crystal.

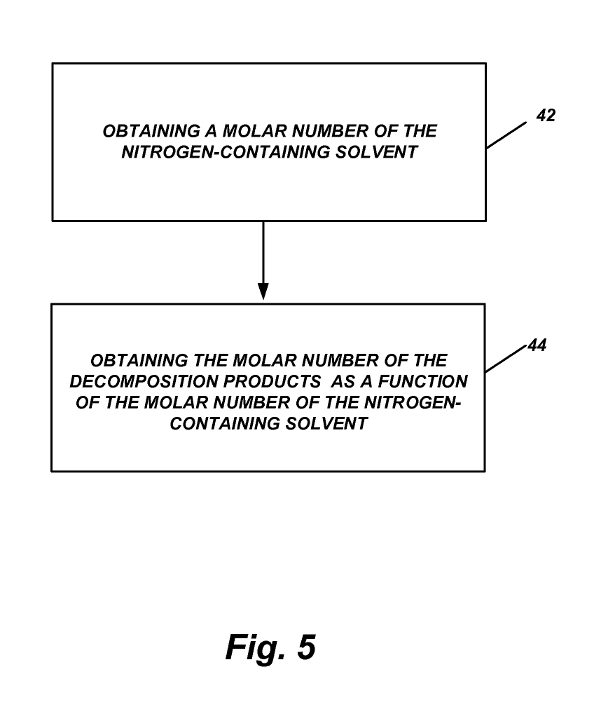

FIG. 5 is a flowchart illustrating an exemplary method for determining the additional amounts of the decomposition products 30 to be added in block 38 of FIG. 4. The additional amounts of decomposition products 30 are typically at least equivalent, within a factor of 100, to a molar number of the decomposition products 30 that comprise H₂ or an amount of hydrogen, and are determined according to equations (3) or equations analogous to equations (3). The molar number of the decomposition products 30 that comprise H₂, or an amount of hydrogen, may be determined by the following steps, for example.

Block 42 represents obtaining a molar number of the nitrogen-containing solvent 28 as a function of equilibrium constant K, and fugacity ratio Kᵥ of the decomposition reactions (e.g., using equations (1)-(5) and/or using the algorithms in the theoretical calculations section), at a temperature and pressure of the nitrogen-containing solvent 28 used during the growing step.

Block 44 represents obtaining the molar number of the decomposition products 30 that comprise H₂, or an amount of hydrogen, as a function of the molar number of the nitrogen-containing solvent 28, using equations (3). Then, additional amounts of the decomposition products 30 may be added to the vessel 10, wherein the additional amounts are to within a factor of 100 of the molar number of the decomposition products 30 that comprise the H₂ (e.g., hydrogen-containing compound 32 or an amount of hydrogen) and/or nitrogen containing compounds, and are produced due to the decomposition reactions (equations (1)-(5)). The additional amounts of decomposition products 30 typically comprise at least some hydrogen, e.g., H₂ or a hydrogen moiety. The nitrogen-containing solvent 28 may be NH₃, and the additional amounts of the decomposition products 30 may be such that a molar amount of NH₃ present in the solvent is greater than what it would have been without the addition of the additional amounts of the decomposition products 30.

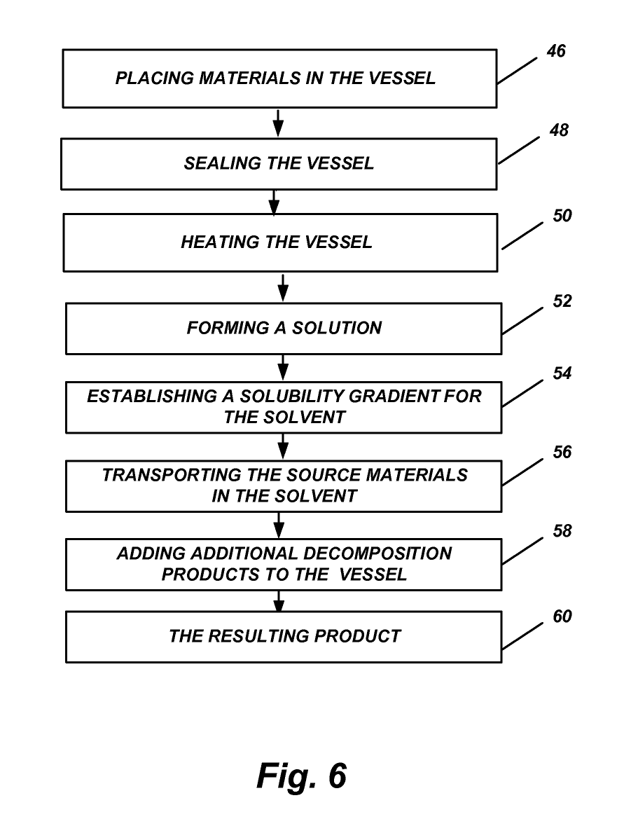

FIG. 6 is a flow chart illustrating another method for obtaining or growing a group-III nitride crystal using the apparatus of FIG. 3, and according to another embodiment of the present invention.

Block 46 represents placing materials, comprising one or more group-III seed crystals 24, one or more group-III-containing source materials 26, and a nitrogen-containing solvent 28 in the reactor vessel 10, wherein the source materials 26 are placed in a first zone or source materials zone (e.g., 22a), the seed crystals 24 are placed in a second zone or seed crystals zone (e.g., 22b), and the nitrogen containing solvent 28 is in both the first zone 22a and the second zone 22b. The seed crystals 24 comprise a group-III single seed crystal; the source materials 26 comprise a group-III-containing compound, a group-III element in its pure elemental form, or a mixture thereof, i.e., a group-III-nitride monocrystal, a group-III-nitride polycrystal, a group-III-nitride powder, group-III-nitride granules, or other group-III-containing compound; and the nitrogen-containing solvent 28 is NH₃ or one or more of its derivatives. Other possible nitrogen-containing compounds or solvents 28 include, but are not limited to: N₂H₄, N₃H₅, N₄H₆, N₃H₃, N₂H₂, N₂ and NH.

An optional mineralizer may be placed in the vessel 10 as well, wherein the mineralizer increases the solubility of the source materials 26 in the nitrogen-containing solvent 28 as compared to the nitrogen-containing solvent 28 without the mineralizer.

Block 48 represents sealing or closing the vessel 10 to form a closed vessel 10.

Block 50 represents heating the vessel 10, for example, according to blocks 52-54 below.

Block 52 represents forming, in a first zone 22a of the vessel 10, a solution of the source materials 26 in the nitrogen-containing solvent 28 in the first zone 22a. The vessel 10 may be heated to conditions such that the vessel 10 is at elevated temperatures (between 23° C. and 1000° C.) and high pressures (between 1 atm and, for example, 30,000 atm). Under these temperatures and pressures, the nitrogen-containing fluid 28 may become or remain a supercritical fluid which normally exhibits enhanced solubility of the source materials 26 into the solvent 28. The solubility of the source materials 26 into the nitrogen-containing solvent 28 is dependent on the temperature, pressure and density of the solvent 28, among other things.

Block 54 represents establishing a solubility gradient for the solvent 28 between the first zone 22a and the second zone 22b, such that a solubility of the source materials in the nitrogen-containing solvent 28 in the first zone 22a is higher than a solubility of the source materials 26 in the nitrogen-containing solvent 28 in the second zone 22b. For example, the source materials zone 22a and seed crystals zone 22b temperatures may range between 0° C. and 1000° C., and the temperature gradients may range between 0° C. and 1000° C.

Block 56 represents transporting the source materials 26 in the solvent 28 from the first zone 22a to the seed crystals 24 in the second zone 22b by establishing motion of the solvent 28 between the first zone 22a and the second zone 22b. Fluid motion may be established between these two zones 22a, 22b, for example, by making use of natural convection, so that it is possible to transport the dissolved source materials 26 from the higher solubility zone 22a to the lower solubility zone 22b, where the source materials then deposits themselves onto the seed crystals 24. Blocks 54-56 therefore further represent causing the source materials in the nitrogen-containing solvent 28 to come out of the solution in the second zone 22b, due to the lower solubility in the second zone 22b as compared to the higher solubility in the first zone 22a, and then deposit on the seed crystals 24, thereby growing the group-III nitride crystal.

Block 58 represents adding additional amounts of the decomposition products 30 to the solvent in the closed vessel 10 (for example, H₂, N₂, and N₂H₄, or other hydrogen containing compound(s) or hydrogen moiety), which form during the various decomposition reactions of the nitrogen-containing solvent 28, to the closed vessel 10 or vessel 10 after the sealing step of block 48. In some embodiments, the additional amounts of decomposition products 30 are added before, during, or immediately after, the filling process of adding solvent 28 for the growth of the crystals. Block 58 may also comprise adding a hydrogen-containing compound 32 to the nitrogen-containing solvent 28 to offset the decomposition of the nitrogen-containing solvent 28 and/or mass loss due to diffusion of H₂ out of the closed vessel 10. This step may comprise adding one or more hydrogen-containing 32 and nitrogen-containing compounds, or one or more compounds 32 comprising both a nitrogen and hydrogen amount, moiety, or compound, or the hydrogen-containing compound 32 or nitrogen-containing compound, to the solvent 28 in the vessel 10 at any time during the method.

Block 60 comprises the resulting product created by the process, namely, a group-III-nitride crystal grown by the method described above. A group-III-nitride substrate may be created from the group-III-nitride crystal, and a device may be created using the group-III-nitride substrate. For example, a GaN crystal may be grown using the method. The method increases the yield of group-III nitride crystal that is grown in a given time period.

In FIG. 6, the seed crystals 24 may be placed in either 22b or 22a, namely the opposite of the zone 22a or 22b containing the source materials 26. However, the source materials 26 should be in the higher solubility zone and the seed crystals 24 in the lower solubility zone, so that the source materials are transported from the higher solubility zone to the lower solubility zone for deposition on the seed crystals 24.

Possible Modifications an Variations

The nitrogen used during and for the nitride growth can come from the solvent 28, or it can come from the source material 26 if it contains nitrogen, or it can come from both the solvent 28 and the source material 26, for example. If it comes from the solvent 28, in one example, it may be preferable for the nitrogen to come from the NH₃ and not N₂ since the bond strength of N₂ is considerably higher than NH₃, in which case the less N₂ present in the system, the more N present for growth. In this embodiment, the smaller the amount of undecomposed solvent 28 the better.

In another example, there can be a trade off between adding additional decomposition materials. For example, when the absolute pressure of the system increases due to the increase in density of gases within the vessel, a balance may be struck, in some embodiments, between additional material added and the pressure increase (only if the engineering of the vessel makes it pressure limited). The balance may be pressure, temperature, solvent dependent and may be determined by indirect methods (e.g., the effect the addition of the decomposition products has on the growth of the GaN and pressure of the system).

In another example, the addition of N₂ might result in a nitrogen rich environment, which may change the stoichiometry of the growing GaN crystal making it nitrogen richer than it would be without the additional nitrogen. In other examples, the concentration of N₂ and/or active N may change.

The amount of hydrogen containing compound added may vary depending on whether the goal is to (1) reduce solvent decomposition, (2) control a ratio among the one or more decomposition product(s), or (3) reduce the amount of hydrogen generated. The limiting factors that can be considered (for pressure limited vessels), are that the total system pressure is a constant. Therefore, in one example, by adding additional hydrogen, the amount of initial NH₃ might need to be reduced. The following are further examples:

(1) The desired amount can be the point where the NH₃ concentration peaks in solution (under total system pressure constraint). Without the pressure constraint, any amount might be acceptable and is probably desirable.

(2) In an example that controls the ratio between decomposition products to obtain a desired ratio, an exact amount might be used. This might be determined through experiment.

(3) In one example that reduces the amount of H₂ generated, N₂ might be added to the system, for example, adding as much N₂ to the system such that there is still the desired amount of NH₃ present (it is not necessarily the maximum possible, but any value deemed necessary for successful growth; this might be useful if the only desire is to reduce H₂, for example).

(4) In one example that adds H₂ to extend the growth duration due to mass loss from diffusion out of the reactor walls, the amount of H₂ may be chosen to match the amount of H₂ predicted to be lost during the growth period. This may be determined experimentally or through experience gained across multiple growth runs.

Advantages and Improvements

Due to thermal equilibrium, all chemical reactions equilibrate to establish a finite mass balance between reactants and products described by the equilibrium constant of the reaction. This equilibrium is a function of temperature, pressure and density of the various compounds involved in the reaction. In the nitrogen-containing solvent used to grow group-III nitride crystals, it is possible to use NH₃ as the primary solvent compound. Other possible compounds include, but are not limited to: N₂H₄, N₃H₅, N₄H₆, N₃H₃, N₂H₂, N₂ and NH. Most of these compounds will eventually, through various chemical reactions, decompose into N₂ and H₂. The H₂, which is a very light molecule, has the tendency to diffuse out of the walls of the vessel, leading to mass loss within the closed vessel. Due to thermal equilibrium, over time, NH₃ and/or the nitrogen-containing solvent, will decompose further to make up for the loss in H₂ due to the leakage, thereby reducing the effective amount of nitrogen-containing solvent for growth of the group-III nitride.

The present invention adds additional decomposition products, which form during the various decomposition reactions of the nitrogen-containing solvent (for example, H₂, N₂, and N₂H₂) to the closed vessel used during growth to shift the balance between the reactants, i.e. the nitrogen-containing solvent, and the decomposition products towards the reactant side according to Le Chatelier's principle. This has at least three immediate benefits.

First, by carefully selecting the appropriate decomposition product(s), the ratio of the various nitrogen-containing solvents to the one or more decomposition product(s), and the ratio among the one or more decomposition product(s), while also deliberately adding these decomposition product(s) to the closed vessel, it is possible to increase the effective amount of nitrogen-containing solvent present during the growth period. As an example, this would include adding additional N₂ to the initial NH₃ amount filled into vessel. This may result in less NH₃ decomposing into various decomposition products such as H₂ and N₂, thereby increasing the effective amount of NH₃ present during growth.

Another benefit of adding decomposition products to the initial fluids is, if chosen wisely, that the adding may result in a reduction in the amount of H₂ generated during the decomposition reactions. This, in turn, may reduce the partial pressure of H₂ within the closed vessel, thereby reducing the driving force for H₂ to diffuse out of the vessel. By reducing the amount of H₂ diffusing out of the vessel, mass loss out of the vessel is further reduced, thereby potentially increasing the time during which growth may occur before the conditions within the vessel change from the optimal, intended growth conditions.

Another benefit of adding H₂, in particular, to the closed vessel, either before or during the growth, is that not only will the equilibrium reaction between the nitrogen-containing solvent and its decomposition products, including H₂, be pushed towards the reactants side (nitrogen-containing solvent), but the addition of H₂ will also provide a larger absolute amount of H₂ in the system, thereby extending the amount of time it would take before all the additional H₂, and the H₂ which may form due to the decomposition of the nitrogen-containing solvent, diffuses out of the vessel. This prevents the reduction of the effective amount of nitrogen-containing solvent to a level that is not favorable for growth anymore.

The end results of this process are group-III nitride single crystal substrates, or devices grown on substrates, grown using the supercritical fluid as the transport method for growth. With the present invention, the growth period during which growth can be actively persuaded is extended, due to the decrease in mass loss of H₂ and due to the decrease in thermal decomposition of NH₃ during the growth period.

### REFERENCES

The following references are incorporated by reference herein:
[1] Derived from equation 29, page 716 of Hougen Watson, “Chemical Process Principles”, John Wiley, New York, (1945).
[2] FIG. 156, page 712 of Hougen Watson, “Chemical Process Principles”, John Wiley, New York, (1945).
[3] FIG. 156a, page 718 of Hougen Watson, “Chemical Process Principles”, John Wiley, New York, (1945).

### CONCLUSION

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. A method for ammonothermally growing one or more group-III nitride crystals in a vessel, comprising:
using a nitrogen-containing solvent to dissolve and transport one or more group-III-containing source materials to one or more group-III nitride seed crystals, wherein one or more decomposition products form during one or more decomposition reactions of the nitrogen-containing solvent;
growing the group-III nitride crystals on the seed crystals using the dissolved source materials; and
adding one or more hydrogen-containing and one or more nitrogen-containing compounds to the vessel, or adding one or more hydrogen-containing compounds or one or more nitrogen-containing compounds to the vessel, during or before the growing step, wherein the hydrogen-containing and the nitrogen-containing compounds, or the hydrogen-containing compounds or the nitrogen-containing compounds affect equilibrium of the decomposition reactions of the solvent.

2. The method of claim 1, wherein hydrogen-containing compound is Hydrogen (H₂).

3. The method of claim 1, wherein the hydrogen-containing compound and the nitrogen-containing compounds, or the nitrogen-containing compounds or the nitrogen-containing compounds, comprise one or more additional amounts of the decomposition products.

4. The method of claim 3, wherein the additional amounts of the decomposition products comprise Hydrogen (H₂).

5. The method of claim 3, wherein the nitrogen-containing solvent is ammonia and the additional amounts of the decomposition products comprise at least 0.01 moles of Hydrogen (H₂).

6. The method of claim 3, wherein the nitrogen-containing solvent is ammonia and the additional amounts of the decomposition products comprise at least 0.01 moles of H₂ and at least 0.01 moles of N₂.

7. The method of claim 3, wherein the additional amounts of the decomposition products comprise exogenous matter that is exogenous to the decomposition reactions.

8. The method of claim 3, wherein the additional amounts of the decomposition products are at least equivalent, within a factor of 100, to a molar number of the decomposition products that comprise the hydrogen-containing and the nitrogen-containing compounds, or the decomposition products comprising the hydrogen-containing compounds or the nitrogen-containing compounds.

9. The method of claim 3, wherein the nitrogen-containing solvent is ammonia (NH₃) and the additional amounts of the decomposition products are such that a molar amount of ammonia present in the solvent is greater than what it would have been without the addition of the additional amounts of the decomposition products.

10. The method of claim 1, wherein the nitrogen-containing compound is Nitrogen (N₂).

11. The method of claim 1, further comprising:
forming, in a first zone of the vessel, a solution of the source materials in the nitrogen-containing solvent; and
transporting the solution from the first zone to the seed crystal in a second zone of the vessel by establishing motion of the nitrogen-containing solvent between the first zone and the second zone, so that the group-III nitride crystal is grown on the seed crystals in the second zone.

12. The method of claim 1, wherein a balance between the nitrogen-containing solvent and the decomposition products is shifted according to Le Chatelier's principle to increase molar amounts of non-decomposed nitrogen-containing solvent and reduce decomposition of the nitrogen-containing solvent.

13. The method of claim 1, further comprising:
(1) placing, within the vessel, the source materials in a first zone of the vessel, and the seed crystals in a second zone of the vessel, wherein the solvent is in the first zone and the second zone;
(2) sealing the vessel;
(3) heating the vessel to elevated temperatures and high pressures so that the solvent becomes a supercritical fluid and exhibits enhanced solubility of the source materials into the solvent, wherein the solubility of the source materials into the solvent is dependent on the solvent's temperature, pressure and density;
(4) establishing a solubility gradient between the first zone and the second zone, such that a solubility of the source materials in the solvent in the first zone is higher than a solubility of the source materials in the solvent in the second zone;
(5) establishing motion of the solvent between the first zone and the second zone to transport the source materials in the solvent from the first zone to the second zone, to grow the group-III nitride crystal on the seed crystals; and
(6) adding the hydrogen-containing and the nitrogen-containing compounds, or the hydrogen-containing compounds or the nitrogen-containing compounds, to the solvent in the vessel at any time during the method.

14. A group-III nitride crystal grown using the method of claim 1.

15. A method of fabricating a group-III nitride crystal in a closed vessel, comprising:
adding a hydrogen-containing and a nitrogen-containing compound, or adding the hydrogen-containing compound or the nitrogen-containing compound, to a nitrogen-containing solvent used with group-III-containing source materials during ammonothermal growth of the group-III nitride crystal on one or more group-III seed crystals, to offset decomposition of the nitrogen-containing solvent and mass loss due to diffusion of hydrogen out of the closed vessel.
